(19) United States
(12) Patent Application Publication
(10) Pub. No.: US 2026/0304594 A1
(43) Pub. Date: Oct. 1, 2026

(54) CIRCUIT BOARD AND ELECTRICAL DEVICE HAVING THE SAME

(71) Applicant: PEGATRON CORPORATION, TAIPEI CITY (TW)

(72) Inventors: YU-XUAN CHEN, TAIPEI CITY (TW); YI-LUN HUANG, TAIPEI CITY (TW); CHIN-CHIEN CHANG, TAIPEI CITY (TW)

(21) Appl. No.: 19/466,534

(22) Filed: Feb. 2, 2026

(30) Foreign Application Priority Data
Feb. 5, 2025 (TW) 114104057

(51) Int. Cl. H05K 1/02; H05K 1/18

(52) U.S. Cl. CPC H05K 1/0203; H05K 1/18; H05K 2201/064

(57) ABSTRACT

A circuit board and an electrical device. The circuit board includes a board body, a first chip module, a second chip module, and a plurality of fastening elastic pieces. The board body has a plurality of fastening holes, a first common fastening hole, and a second common fastening hole. A gap is between the first chip module and the second chip module. The plurality of fastening elastic pieces is disposed on two sides of both the first chip module and the second chip module. Two of the fastening elastic pieces are fastened together to the first common fastening hole located on one side of the gap and between two of the fastening holes. Another two of the fastening elastic pieces are fastened together to the second common fastening hole located on the other side of the gap and between another two of the fastening holes.

### CROSS-REFERENCE TO RELATED PATENT APPLICATION

This application claims the benefit of priority to Taiwan Patent Application No. 114104057, filed on February 5, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a circuit board, and more particularly to a circuit board having multiple chip modules and a heat pipe cooling module, and an electrical device having the circuit board.

### BACKGROUND OF THE DISCLOSURE

To enhance graphics processing capabilities of a computer, a circuit board usually includes an independent graphics processing unit in addition to the central processing unit. Furthermore, the graphics processing unit has multiple display memory units. As a result, the available space on the circuit board for receiving a heat pipe cooling module has become more limited. In particular, the fastening holes passing through the circuit board are required to secure the heat pipe cooling module.

Furthermore, the positioning of the fastening holes needs to consider the symmetry of arrangements to avoid uneven pressure applied to the chip modules of the graphics processing unit. Moreover, the placement of the heat pipe cooling module also affects the bending curvature of the heat pipe. In addition, the solution to the above problem is made more stringent by the miniaturization of the board area. Therefore, how to improve the structural design to enhance the space utilization of the circuit board and overcome the aforementioned drawbacks has become one issue to be addressed in this technical field.

### SUMMARY OF THE DISCLOSURE

In response to the above-referenced technical inadequacies, the present disclosure provides a circuit board to improve the space utilization of the circuit board by reducing the space occupied by the fastening holes on the circuit board.

In order to solve the above-mentioned problems, one of the technical aspects adopted by the present disclosure is to provide a circuit board, which includes a board body, a first chip module, a second chip module, and a plurality of fastening elastic pieces. The board body has a plurality of fastening holes, a first common fastening hole, and a second common fastening hole. The first chip module and the second chip module are disposed on the board body. A gap is between the second chip module and the first chip module. The fastening elastic pieces are disposed on two sides of the first chip module and the second chip module. Two of the plurality of fastening elastic pieces are fastened together to the first common fastening hole, and another two of the plurality of fastening elastic pieces are fastened together to the second common fastening hole. The first common fastening hole is located on one side of the gap and between two of the plurality of fastening holes, while the second common fastening hole is located on the other side of the gap and between another two of the plurality of fastening holes.

In order to solve the above-mentioned problems, another one of the technical aspects adopted by the present disclosure is to provide an electrical device that includes the circuit board, a plurality of display memory units disposed on the circuit board and located at a peripheral of the first chip module, a heat pipe configured to abuts against the first chip module and the second chip module, and at least one cooling fan connected to the heat pipe.

Therefore, in the circuit board provided by the present disclosure, by virtue of commonly sharing the first common fastening hole and the second common fastening hole, the total number of fastening holes can be reduced. In addition, the spatial utilization of the board body of the circuit board is enhanced, which is advantageous for the placement of electronic components and circuit routing, as well as for enhancing structural stability.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a partial schematic top view of a circuit board according to the present disclosure;

FIG. 2 is a schematic top plan view of the circuit board combined with a heat pipe cooling module according to the present disclosure;

FIG. 3 is a schematic top view of the circuit board according to a second embodiment of the present disclosure;

FIG. 4 is a schematic view of the circuit board according to a third embodiment of the present disclosure;

FIG. 5 is a schematic view of the circuit board according to a fourth embodiment of the present disclosure;

FIG. 6A is a schematic side view illustrating relevant parameters of a fastening elastic piece according to the present disclosure; and

FIG. 6B is a schematic top plan view illustrating relevant parameters of the fastening elastic piece according to the present disclosure.

### DETAILED DESCRIPTION OF THE EXEMPLARY EMBODIMENTS

### First Embodiment

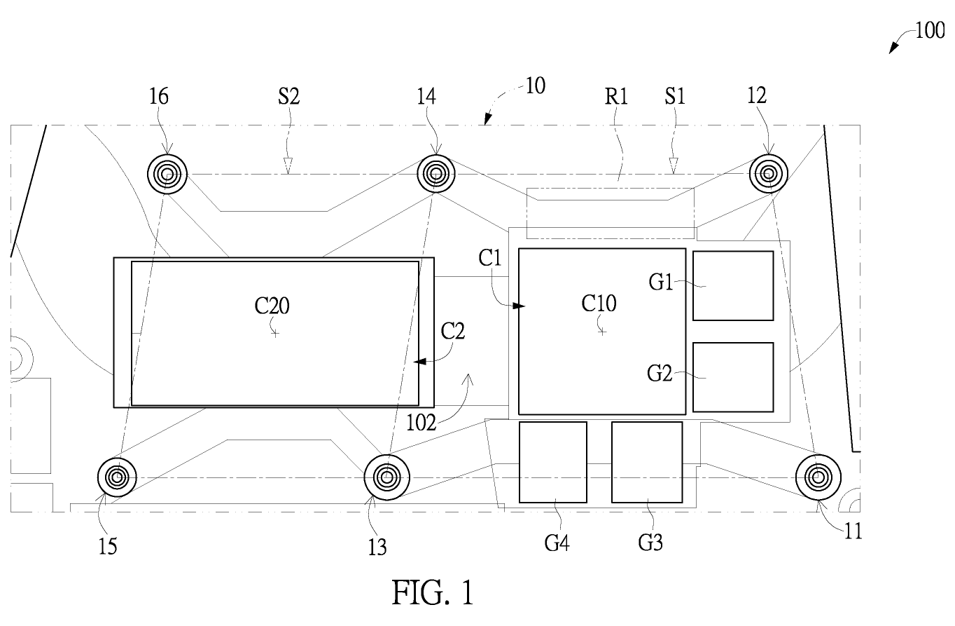

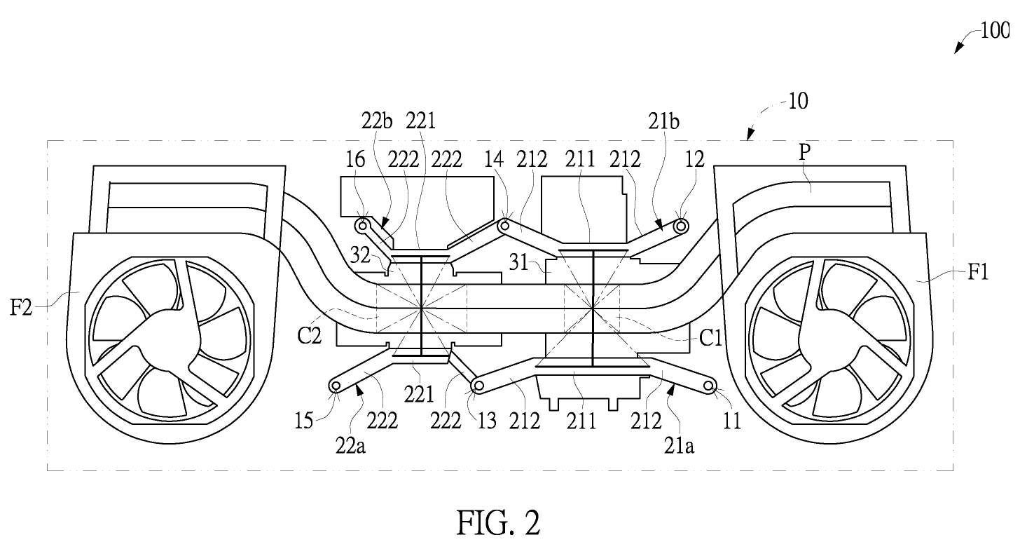

Referring to FIG. 1 and FIG. 2, one embodiment of the present disclosure provides a circuit board 100 and an electrical device having the circuit board 100. For example, the electrical device may be a laptop, any other types of computers, or any device requiring such a circuit board.

The circuit board 100 includes a board body 10, a first chip module C1, and a second chip module C2. The first chip module C1 and the second chip module C2 are disposed on the board body 10. A gap 102 is between the second chip module C2 and the first chip module C1.

For example, the first chip module C1 can be a graphics processing unit (GPU), and the second chip module C2 can be a central processing unit (CPU). In some embodiments, a plurality of display memories G1, G2, G3, G4 may be disposed at a periphery of the first chip module C1 to store graphical data that has been processed by or is about to be read by the first chip module C1. Furthermore, due to circuit routing plans or other design considerations, the circuit board 100 also has a restrict region R1, where the formation of fastening holes is prohibited.

To dissipate the residual heat generated during the operation of the first chip module C1 and the second chip module C2, the circuit board 100 also includes a heat pipe cooling module, and the heat pipe cooling module includes a heat pipe P and two cooling fans F1, F2. The number of cooling fans can be at least one. The heat pipe P abuts against the first chip module C1 and the second chip module C2, and the two cooling fans F1, F2 are connected to the two ends of the heat pipe P.

The board body 10 may include a plurality of fastening holes configured to cooperate with a plurality of fastening elastic pieces to secure the heat pipe P. In this embodiment, the number of the fastening holes is four, but it is not limited thereto. As the space available on the board body 10 for providing the fastening holes has become more limited, this embodiment further includes commonly-shared fastening holes that include a first common fastening hole 13 and a second common fastening hole 14 so as to reduce the total number of fastening holes.

The first common fastening hole 13 is located between two of the fastening holes, and the second common fastening hole 14 is located between another two of the fastening holes. A feature of this embodiment is that, a plurality of fastening elastic pieces (21a, 21b, 22a, 22b) is disposed on two sides of both the first chip module C1 and the second chip module C2. Two of the fastening elastic pieces (21a, 22a) are commonly fastened to the first common fastening hole 13, and another two of the fastening elastic pieces (21b, 22b) are commonly fastened to the second common fastening hole 14.

Specifically, the board body 10 has a first fastening hole 11, a second fastening hole 12, a first common fastening hole 13, a second common fastening hole 14, a third fastening hole 15, and a fourth fastening hole 16. The first fastening hole 11 and the second fastening hole 12 are located on the outer side of the first chip module C1, that is, the side by the first chip module C1 away from the second chip module C2. The third fastening hole 15 and the fourth fastening hole 16 are located on the outer side of the second chip module C2, that is, the side by the second chip module C2 away from the first chip module C1.

The first common fastening hole 13 is located on the side by the gap 102 and between the first fastening hole 11 and the third fastening hole 15. The first fastening hole 11, the first common fastening hole 13, and the third fastening hole 15 are arranged substantially in a straight line in sequence.

The second common fastening hole 14 is located on the other side of the first common fastening hole 13 and between the second fastening hole 12 and the fourth fastening hole 16. The second fastening hole 12, the second common fastening hole 14, and the fourth fastening hole 16 are arranged substantially in a straight line in sequence.

Referring to FIG. 2, the circuit board 100 of this embodiment also includes a plurality of fastening elastic pieces for holding the heat pipe P on the board body 10. An upper side and a lower side of the first chip module C1 include a first fastening upper elastic piece 21b and a first fastening lower elastic piece 21a, respectively. The terms “upper” and “lower” are used merely to distinguish their relative positions. In some embodiments, the shapes of the first fastening upper elastic piece 21b and the first fastening lower elastic piece 21a can be the same or different.

Furthermore, an upper side and a lower side of the second chip module C2 include a second fastening upper elastic piece 22b and a second fastening lower elastic piece 22a, respectively. The shapes of the second fastening upper elastic piece 22b and the second fastening lower elastic piece 22a can be the same or different.

Referring to FIG. 2, the first fastening lower elastic piece 21a located at the lower side of the first chip module C1 and the second fastening lower elastic piece 22a located at the lower side of the second chip module C2 are commonly fastened to the first common fastening hole 13. The first fastening upper elastic piece 21b located at the upper side of the first chip module C1 and the second fastening upper elastic piece 22b located at the upper side of the second chip module C2 are commonly fastened to the second common fastening hole 14.

Specifically, the first fastening upper elastic piece 21b and the first fastening lower elastic piece 21a each include a first connection part 211 and a pair of first elastic arms 212. The pair of first elastic arms 212 is connected to the two ends of the first connection part 211. The first connection part 211 is connected to a contact base 31. The second fastening upper elastic piece 22b and the second fastening lower elastic piece 22a each include a second connection part 221 and a pair of second elastic arms 222. The pair of second elastic arms 222 is connected to the two ends of the second connection part 221. The second connection part 221 is connected to another contact base 32. One of the first elastic arms 212 of the first fastening lower elastic piece 21a and one of the second elastic arms 222 of the second fastening lower elastic piece 22a are commonly fastened to the first common fastening hole 13. One of the first elastic arms 212 of the first fastening upper elastic piece 21b and one of the second elastic arms 222 of the second fastening upper elastic piece 22b are commonly fastened to the second common fastening hole 14.

The design process for planning the board body 10 of this embodiment is described below. For ease of description, directional terms such as up, down, left, and right are used with reference to the drawings for illustrative purposes only. In the first step, the first fastening hole 11 (or a hole 1) is defined based on the placement constraints of the first chip module C1. In this embodiment, the position of the first fastening hole 11 is defined first because the four display memories G1, G2, G3, G4 are located to the right side and the lower side of the first chip module C1. Due to the arrangement of the display memories G1, G2, G3, G4, the space available for a hole in the bottom-right corner of the first chip module C1 is the most restricted.

In the second step, the second fastening hole 12 (or a hole 2) is defined in the top-right corner of the first chip module C1 according to the heat pipe design plan. Referring to FIG. 2, the heat pipe design plan includes the number, the width, the bending direction, etc., of the heat pipes.

In the third step, as shown in FIG. 1, based on the already defined first fastening hole 11 and second fastening hole 12, the first common fastening hole 13 (or a hole 3) and the second common fastening hole 14 (or a hole 4) are defined in the available space on the other side (i.e., the left side) of the first chip module C1, and arranged symmetrically along the vertical midline of the first chip module C1. In this embodiment, the first fastening hole 11, the second fastening hole 12, the first common fastening hole 13, and the second common fastening hole 14 form a trapezoid, with the purpose of avoiding the display memory G4.

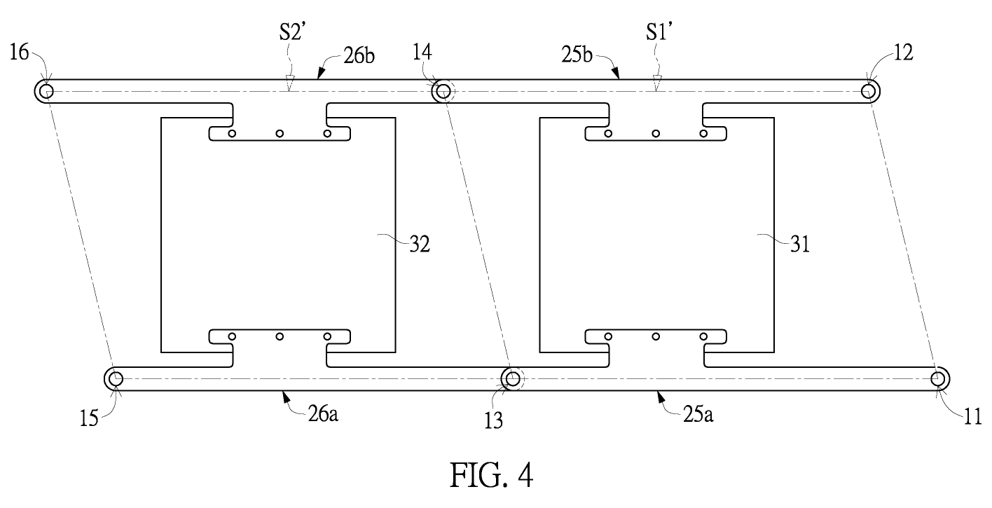

Referring to FIG. 4, without affecting the components surrounding the first chip module C1, the four fastening holes (11, 12, 13, 14) around the first chip module C1 can also be varied to form a parallelogram.

In the fourth step, as shown in FIG. 1, based on the positions of the first common fastening hole 13 and the second common fastening hole 14, the third fastening hole 15 (or a hole 5) and the fourth fastening hole 16 (or a hole 6) are defined in the available space on the other side (the left side) of the second chip module C2, and arranged in a parallelogram.

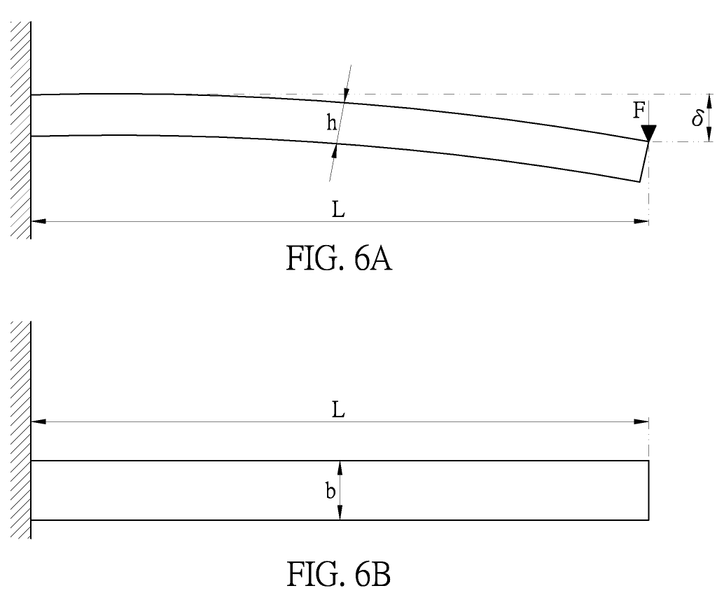

In fifth step, as shown in FIG. 6A and FIG. 6B, based on the planned positions of the fastening holes, this embodiment further adjusts the parameters of each of the fastening elastic pieces, such that a fastening pressure F of the elastic arms on both sides of the same fastening elastic piece is equal. Additionally, based on the positional geometric arrangement of the fastening holes, the fastening pressure F can be maintained at the geometric center of the chip modules. The aforementioned parameters include a length L, a width b, a thickness h of the elastic arm, and a compressible stroke δ. Furthermore, the fastening pressure F also refers to the Young's modulus E of the material of the fastening elastic piece. The formula for the fastening pressure F can be expressed as: F = (δ * b * h³ * E) / (4L³).

For example, according to the plan in FIG. 1, a first geometric shape S1 is a trapezoid. The fastening pressure of the first elastic arms 212 on both sides of the first fastening lower elastic piece 21a can be 0.677 kilogram-force (kgf), and the fastening pressure of the first elastic arms 212 on both sides of the first fastening upper elastic piece 21b can be 1.075 kilogram-force (kgf). Therefore, the first chip module C1 can have a symmetrical fastening pressure, with the force being applied to a geometric center C10 of the first chip module C1.

For example, according to the plan in FIG. 1, a second geometric shape S2 is a parallelogram. The two second elastic arms along the diagonal of the parallelogram have the same fastening pressure. For instance, the second elastic arm 222 on the right side of the second fastening lower elastic piece 22a and the second elastic arm 222 on the left side of the second fastening upper elastic piece 22b can have a pressure of 0.996 kilogram-force (kgf). The second elastic arm 222 on the left side of the second fastening lower elastic piece 22a and the second elastic arm 222 on the right side of the second fastening upper elastic piece 22b can have a pressure of 0.740 kilogram-force (kgf). Therefore, the second chip module C2 can have a symmetrical fastening pressure, by the force applied to a geometric center C20 of the second chip module C2.

In the sixth step, the fastening elastic pieces are fastened together. In other words, the first fastening lower elastic piece 21a and the second fastening lower elastic piece 22a are fastened together to the first common fastening hole 13, and the first fastening upper elastic piece 21b and the second fastening upper elastic piece 22b are fastened together to the second common fastening hole 14. Compared to each conventional chip module requiring four fastening holes, this embodiment can save two fastening holes. This not only meets the new design requirements for circuit boards but also saves on fastening components.

### Second Embodiment

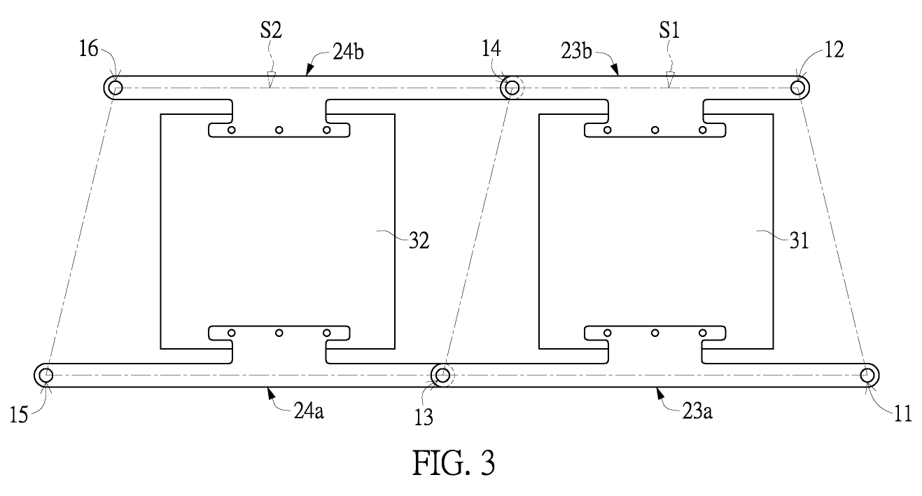

Refer to FIG. 3, the difference between this embodiment and the previous embodiment is the shapes of the fastening elastic pieces. A first fastening lower elastic piece 23a and a second fastening lower elastic piece 24a are fastened together to the first common fastening hole 13. A first fastening upper elastic piece 23b and a second fastening upper elastic piece 24b are fastened together to the second common fastening hole 14. The first fastening hole 11, the second fastening hole 12, the first common fastening hole 13, and the second common fastening hole 14 can be arranged to form the trapezoid-shaped first geometric shape S1. The first common fastening hole 13, the second common fastening hole 14, the third fastening hole 15, and the fourth fastening hole 16 can be arranged to form the parallelogram-shaped second geometric shape S2.

### Third Embodiment

Referring to FIG. 4, various spaces can be made available depending on the arrangement of components on the circuit board 100. For example, a first geometric shape S1’ formed by the first fastening hole 11, the second fastening hole 12, the first common fastening hole 13, and the second common fastening hole 14 can be a parallelogram. Correspondingly, a second geometric shape S2’ formed by the first common fastening hole 13, the second common fastening hole 14, the third fastening hole 15, and the fourth fastening hole 16 is also a parallelogram. A first fastening lower elastic piece 25a and a second fastening lower elastic piece 26a are fastened together to the first common fastening hole 13. A first fastening upper elastic piece 25b and a second fastening upper elastic piece 26b are fastened together to the second common fastening hole 14.

### Fourth Embodiment

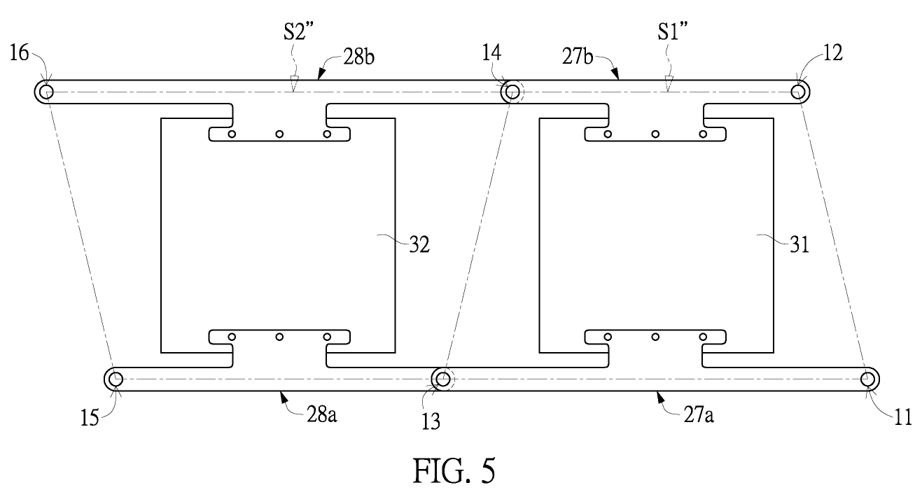

Referring to FIG. 5, various spaces can be made available depending on the arrangement of components on the circuit board 100. For example, a first geometric shape S1” formed by the first fastening hole 11, the second fastening hole 12, the first common fastening hole 13, and the second common fastening hole 14 can be a trapezoid (narrower at the top, wider at the bottom). Correspondingly, a second geometric shape S2” formed by the first common fastening hole 13, the second common fastening hole 14, the third fastening hole 15, and the fourth fastening hole 16 can also be a trapezoid (wider at the top, narrower at the bottom). A first fastening lower elastic piece 27a and a second fastening lower elastic piece 28a are fastened together to the first common fastening hole 13. A first fastening upper elastic piece 27b and a second fastening upper elastic piece 28b are fastened together to the second common fastening hole 14.

### Beneficial Effects of the Embodiments

In conclusion, in the circuit board provided by the present disclosure, by virtue of commonly sharing the first common fastening hole and the second common fastening hole, the total number of fastening holes can be reduced. In addition, the spatial utilization of the board body of the circuit board is enhanced, which is advantageous for the placement of electronic components and circuit routing, as well as for enhancing structural stability.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A circuit board, comprising:
a board body having a plurality of fastening holes, a first common fastening hole, and a second common fastening hole;
a first chip module disposed on the board body;
a second chip module disposed on the board body, wherein a gap is between the second chip module and the first chip module; and
a plurality of fastening elastic pieces disposed on two sides of the first chip module and the second chip module, wherein two of the plurality of fastening elastic pieces are fastened together to the first common fastening hole, and another two of the plurality of fastening elastic pieces are fastened together to the second common fastening hole;
wherein the first common fastening hole is located on one side of the gap and between two of the plurality of fastening holes while the second common fastening hole is located on the other side of the gap and between another two of the plurality of fastening holes.

2. The circuit board according to claim 1, wherein the plurality of fastening elastic pieces include a first fastening upper elastic piece, a first fastening lower elastic piece, a second fastening upper elastic piece, and a second fastening lower elastic piece; the first fastening upper elastic piece and the first fastening lower elastic piece are disposed on the two sides of the first chip module, and the second fastening upper elastic piece and the second fastening lower elastic piece are disposed on the two sides of the second chip module; the first fastening lower elastic piece and the second fastening lower elastic piece are fastened together to the first common fastening hole; and the first fastening upper elastic piece and the second fastening upper elastic piece are fastened together to the second common fastening hole.

3. The circuit board according to claim 2, wherein the first fastening upper elastic piece and the first fastening lower elastic piece each include a first connection part and a pair of first elastic arms, and the pair of first elastic arms is connected to two ends of the first connection part; the second fastening upper elastic piece and the second fastening lower elastic piece each include a second connection part and a pair of second elastic arms, and the pair of second elastic arms is connected to two ends of the second connection part; one of the pair of first elastic arms of the first fastening lower elastic piece and one of the pair of second elastic arms of the second fastening lower elastic piece are fastened together to the first common fastening hole; and the other one of the pair of first elastic arms of the first fastening upper elastic piece and the other one of the pair of second elastic arms of the second fastening upper elastic piece are fastened together to the second common fastening hole.

4. The circuit board according to claim 1, wherein the plurality of fastening holes include a first fastening hole, a second fastening hole, a third fastening hole, and a fourth fastening hole; the first common fastening hole is located between the first fastening hole and the third fastening hole while the second common fastening hole is located between the second fastening hole and the fourth fastening hole.

5. The circuit board according to claim 4, wherein the first fastening hole, the second fastening hole, the first common fastening hole, and the second common fastening hole form a first geometric shape, and a geometric center of the first geometric shape is the same as a geometric center of the first chip module.

6. The circuit board according to claim 5, wherein the first geometric shape is a trapezoid or a parallelogram.

7. The circuit board according to claim 4, wherein the third fastening hole, the fourth fastening hole, the first common fastening hole, and the second common fastening hole form a second geometric shape, and a geometric center of the second geometric shape is the same as a geometric center of the second chip module.

8. The circuit board according to claim 7, wherein the second geometric shape is a trapezoid or a parallelogram.

9. The circuit board according to claim 1, wherein the first chip module is a graphics processing unit, and the second chip module is a central processing unit.

10. An electrical device, comprising:
a circuit board including:
a board body having a plurality of fastening holes, a first common fastening hole, and a second common fastening hole;
a first chip module disposed on the board body;
a second chip module disposed on the board body, wherein a gap is between the second chip module and the first chip module; and
a plurality of fastening elastic pieces disposed on two sides of the first chip module and the second chip module, wherein two of the plurality of fastening elastic pieces are fastened together to the first common fastening hole, and another two of the plurality of fastening elastic pieces are fastened together to the second common fastening hole;
wherein the first common fastening hole is located on one side of the gap and between two of the plurality of fastening holes, and the second common fastening hole is located on the other side of the gap and between another two of the plurality of fastening holes;
a plurality of display memories disposed on the circuit board and located at a peripheral of the first chip module;
a heat pipe configured to abut against the first chip module and the second chip module; and
at least one cooling fan connected to the heat pipe.

11. The electrical device according to claim 10, wherein the plurality of fastening elastic pieces includes a first fastening upper elastic piece, a first fastening lower elastic piece, a second fastening upper elastic piece, and a second fastening lower elastic piece; the first fastening upper elastic piece and the first fastening lower elastic piece are disposed on the two sides of the first chip module; the second fastening upper elastic piece and the second fastening lower elastic piece are disposed on the two sides of the second chip module; and the first fastening lower elastic piece and the second fastening lower elastic piece are fastened together to the first common fastening hole; and the first fastening upper elastic piece and the second fastening upper elastic piece are fastened together to the second common fastening hole.

12. The electrical device according to claim 11, wherein the first fastening upper elastic piece and the first fastening lower elastic piece each include a first connection part and a pair of first elastic arms, the pair of first elastic arms is connected to two ends of the first connection part; the second fastening upper elastic piece and the second fastening lower elastic piece each include a second connection part and a pair of second elastic arms, and the pair of second elastic arms is connected to two ends of the second connection part; one of the first elastic arms of the first fastening lower elastic piece and one of the second elastic arms of the second fastening lower elastic piece are fastened together to the first common fastening hole; and one of the pair of first elastic arms of the first fastening upper elastic piece and one of the pair of second elastic arms of the second fastening upper elastic piece are fastened together to the second common fastening hole.

13. The electrical device according to claim 10, wherein the plurality of fastening holes include a first fastening hole, a second fastening hole, a third fastening hole, and a fourth fastening hole; the first common fastening hole is located between the first fastening hole and the third fastening hole; and the second common fastening hole is located between the second fastening hole and the fourth fastening hole.

14. The electrical device according to claim 13, wherein the first fastening hole, the second fastening hole, the first common fastening hole, and the second common fastening hole form a first geometric shape, and a geometric center of the first geometric shape is the same as a geometric center of the first chip module.

15. The electrical device according to claim 14, wherein the first geometric shape is a trapezoid or a parallelogram.

16. The electrical device according to claim 13, wherein the third fastening hole, the fourth fastening hole, the first common fastening hole, and the second common fastening hole form a second geometric shape, and a geometric center of the second geometric shape is the same as a geometric center of the second chip module.

17. The electrical device according to claim 16, wherein the second geometric shape is a trapezoid or a parallelogram.

18. The electrical device according to claim 10, wherein the first chip module is a graphics processing unit, and the second chip module is a central processing unit.
